(19) United States
(12) Patent Application Publication
(10) Pub. No.: US 2008/0035973 A1
(43) Pub. Date: Feb. 14, 2008

(54) LOW-NOISE SINGLE-GATE NON-VOLATILE MEMORY AND OPERATION METHOD THEREOF

(76) Inventors: Hsin Chang Lin, Chu-pei City (TW); Wen Chien Huang, Chu-pei City (TW); Hao Cheng Chang, Chu-pei City (TW); Cheng Ying Wu, Chu-pei City (TW); Ming Tsang Yang, Chu-pei City (TW)

Correspondence Address: SINORICA, LLC, 528 FALLSGROVE DRIVE, ROCKVILLE, MD, 20850, US

(21) Appl. No.: 11/463,600

(22) Filed: Aug. 10, 2006

(51) Int. Cl. H01L 29/94

(52) U.S. Cl. 257/298

(57) ABSTRACT

The present invention discloses a low-noise single-gate non-volatile memory and an operation method thereof, wherein a transistor and a capacitor structure are embedded in a semiconductor substrate; the electrically-conductive gate of the transistor and the electrically-conductive gate of the capacitor structure are interconnected to form a single floating gate of a memory cell; an ion-doped buried layer is formed between the dielectric layer of the capacitor structure and the semiconductor substrate to reduce the external interference on the capacitor structure and control the initial threshold voltage; a reverse bias may be used to implement the reading, writing, and erasing operations of the single-floating-gate memory cell; in the operation of the low-noise single-gate non-volatile memory having an isolation well, positive and negative voltages may be applied to the drain, the gate, and the silicon substrate/the isolation well to create an inversion layer, and thereby, the absolute voltage, the area of the voltage booster circuit, and the current consumption can be reduced.

### BACKGROUND OF THE INVENTION

1. Field of the Invention

The present invention relates to a non-volatile memory and an operation method thereof, particularly to a low-noise single-gate non-volatile memory and an operation method thereof, wherein the memory can be written or erased with a low voltage and a low current consumption.

2. Description of the Related Art

The CMOS (Complementary Metal Oxide Semiconductor) process has been a common fabrication method for ASIC (Application Specific Integrated Circuit). EEPROM is the abbreviation of Electrically Erasable Programmable Read Only Memory. In EEPROM, data not only can be electrically written and erased but also will not volatilize after power has been turned off; therefore, EEPROM has been extensively used in electronic products.

A non-volatile memory is programmable. In principle, whether the gate voltage is changed or maintained depends on the charging state. In erasing a non-volatile memory, the charges stored thereinside are removed, and the gate voltage is restored to the original values. In the conventional non-volatile memories, the operation voltage is usually over 10 volts; thus, not only the required voltage boostering circuit increases the cost, but also the operation after voltage booster consumes considerable current. Further, when the conventional non-volatile memories, especially embedded products, are fabricated with an advanced process, it usually needs many extra procedures, which increases the difficulties and cost of fabrication. Therefore, all the advanced processes are endeavoring to develop a low-voltage non-volatile memory.

Accordingly, the present invention proposes a low-noise single-gate non-volatile memory and an operation method thereof to overcome the abovementioned problems.

### SUMMARY OF THE INVENTION

The primary objective of the present invention is to provide a low-noise single-gate non-volatile memory and an operation method thereof, wherein two electrically-conductive gates are electrically connected to form single-floating-gate structure; in programming the memory, a really active voltage is applied to the source, or a back bias is applied to the transistor substrate, in order to create a wider depleted source-substrate junction; thereby, current can flow to the floating gate more efficiently, and the current for programming the single-gate non-volatile memory can be greatly reduced.

Another objective of the present invention is to provide a low-noise single-gate non-volatile memory and an operation method thereof, wherein an ion-doped buried layer is formed between the capacitor structure and the semiconductor substrate; thereby, the external interference on the capacitor structure can be minimized, and the initial threshold voltage of the electrically-conductive gate can be well controlled.

Yet another objective of the present invention is to provide a low-noise single-gate non-volatile memory and an operation method thereof, wherein the F-N tunneling current is increased via raising drain voltage and applying a minor voltage to the gate, and the memory is erased with the increased F-N tunneling current; thereby, a high-speed erasion is achieved.

Further another objective of the present invention is to provide a low-noise single-gate non-volatile memory and an operation method thereof, wherein positive voltage and negative voltage are jointly used to achieve the efficacies of low operational current, ultra low operation voltage and high reliability, and to reduce the size of the whole non-volatile memory.

To achieved the abovementioned objectives, the present invention discloses a low-noise single-gate non-volatile memory, wherein a transistor and a capacitor structure are embedded in a semiconductor substrate; the transistor comprises: a first dielectric layer, disposed in the semiconductor substrate or inside an isolation well; a first electrically-conductive gate, stacked on the first dielectric layer; and two high-conductivity first ion-doped regions, separately disposed at both sides of the first electrically-conductive gate, and respectively functioning as the source and the drain; similar to the transistor, the capacitor structure has a sandwich-like top layer-dielectric layer-bottom layer structure and comprises: a second dielectric layer, a second electrically-conductive gate, a second ion-doped region and a second ion-doped buried layer; the first electrically-conductive gate of the transistor and the second electrically-conductive gate of the capacitor structure are separated and electrically interconnected to form a single floating gate of the non-volatile memory; N-type first ion-doped regions, N-type second ion-doped regions and N-type second ion-doped buried layers are to be used for a P-type semiconductor substrate or a P-type isolation well; and P-type first ion-doped regions, P-type second ion-doped regions and P-type second ion-doped buried layers are to be used for an N-type semiconductor substrate or an N-type isolation well.

The present invention also discloses an operation method of the abovementioned low-noise single-gate non-volatile memory, wherein the memory is programmed via that a voltage is applied to the source, or a back-bias is applied to the substrate of the transistor (or source voltage is greater than substrate voltage in writing the memory); the F-N tunneling current is increased via raising gate voltage (or gate voltage is greater than source voltage in erasing the memory) to achieve a high-speed erasion; a negative-voltage device is used to achieve the efficacies of lower operation current and ultra low operation voltage. Further, any modification and variation according to the structure of the low-noise single-gate non-volatile memory disclosed herein and any programming and erasing operation method of the abovementioned low-noise single-gate non-volatile memory disclosed herein are to be also included within the scope of the present invention.

To enable the objectives, technical contents, characteristics, and accomplishments of the present invention to be more easily understood, the embodiments of the present invention are to be described in detail in cooperation with the attached drawings below.

### BRIEF DESCRIPTION OF THE DRAWINGS

FIG. 1 is a sectional view schematically showing the structure of the low-noise single-gate non-volatile memory according to a first embodiment of the present invention;

FIG. 2A is a diagram schematically showing the four-terminal structure of the first embodiment;

FIG. 2B is a diagram schematically showing an equivalent circuit of the structure shown in FIG. 2A;

FIG. 3 is a sectional view schematically showing the structure of the low-noise single-gate non-volatile memory according to a second embodiment of the present invention;

FIG. 4 is a diagram schematically showing the erasing architecture of the second embodiment;

FIG. 5 is a sectional view schematically showing the structure of the low-noise single-gate non-volatile memory according to a third embodiment of the present invention;

FIG. 6 is a diagram schematically showing the erasing architecture of the third embodiment;

FIG. 7 is a sectional view schematically showing the structure of the low-noise single-gate non-volatile memory according to a fourth embodiment of the present invention;

FIG. 8A is a diagram schematically showing the six-terminal structure of the fourth embodiment;

FIG. 8B is a diagram schematically showing an equivalent circuit of the structure shown in FIG. 8A; and

FIG. 9 is a sectional view schematically showing the structure of the s low-noise ingle-gate non-volatile memory according to a fifth embodiment of the present invention.

### DETAILED DESCRIPTION OF THE INVENTION

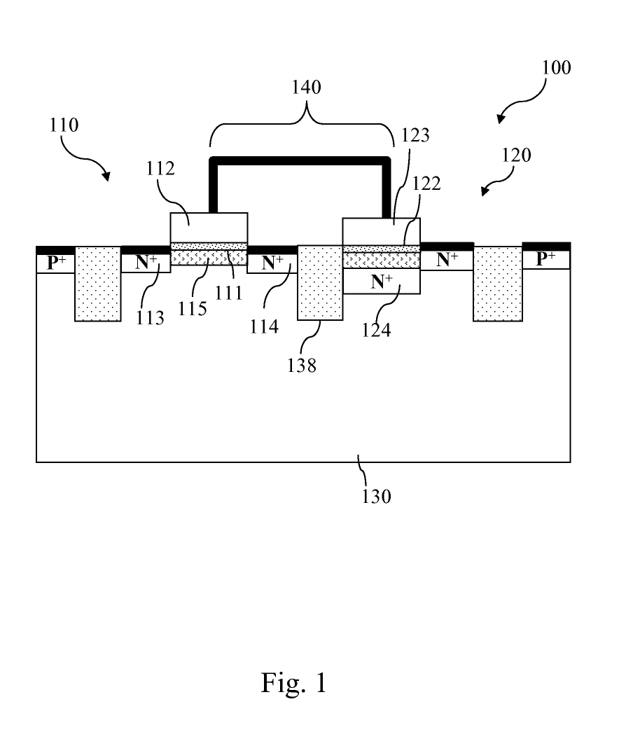

Refer to FIG. 1 a sectional view schematically showing the structure of the low-noise single-gate non-volatile memory according to a first embodiment of the present invention. The low-noise single-gate non-volatile memory structure 100 comprises: an NMOS transistor (NMOSFET) 110 and an N-type capacitor structure 120 with both of them embedded in a P-type semiconductor substrate 130. The NMOS transistor 110 further comprises: a first dielectric layer 111, disposed on the surface of the P-type semiconductor substrate 130; a first electrically-conductive gate 112, stacked on the first dielectric layer 111; and two first ion-doped regions, disposed inside the P-type semiconductor substrate 130, and respectively functioning as the source 113 and the drain 114 with a channel 115 formed between the source 113 and the drain 114. The N-type capacitor structure 120 further comprises: a second ion-doped region 121 and a second ion-doped buried layer 124, respectively disposed in the P-type semiconductor substrate 130; a second dielectric layer 122, disposed above the second ion-doped buried layer 124 and neighboring the second ion-doped region 121; and a second electrically-conductive gate 123, stacked on the second dielectric layer 122; those abovementioned elements form a sandwich-like top layer-dielectric layer-bottom layer capacitor structure. The first electrically-conductive gate 112 of the NMOS transistor 110 and the second electrically-conductive gate 123 on the top of the N-type capacitor structure 120 are separated with an isolation material 138 and electrically interconnected to form a single floating gate 140. The first ion-doped regions, the second ion-doped region 121 and the second ion-doped buried layer 124 are all N-type ion-doped regions.

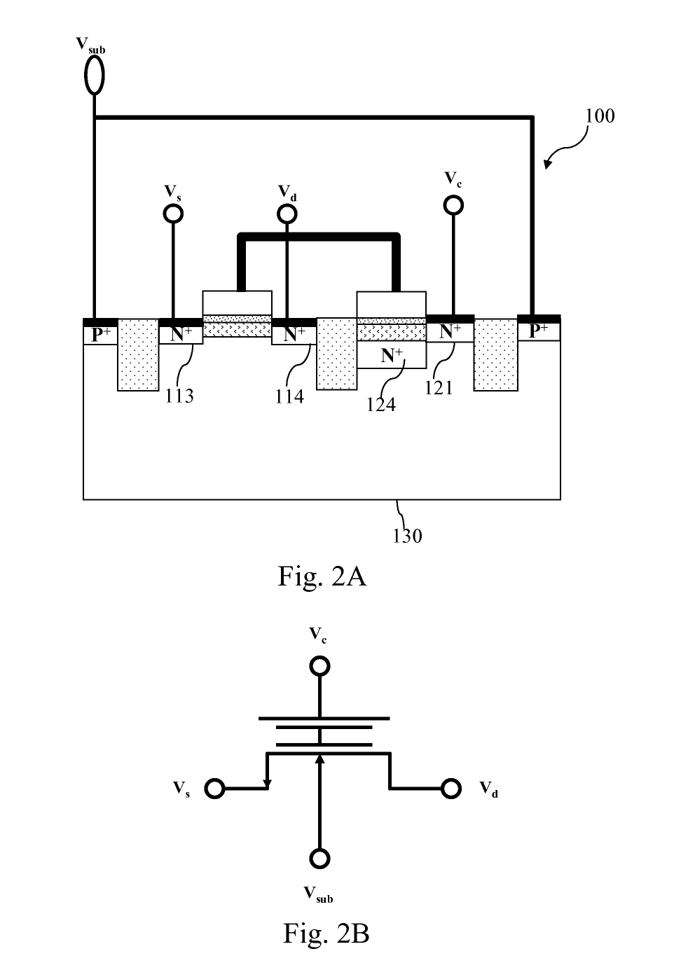

Refer to FIG. 2A. The low-noise single-gate non-volatile memory structure 100 has four terminals, including: the connecting structures of the substrate, the source, the drain, and the control gate; a substrate voltage V_{sub}, a source voltage Vₛ, a drain voltage V_{d}, a control gate voltage V_{c} are respectively applied to the substrate 130, the source 113, the drain 114, and the second ion-doped region 121. Refer to FIG. 2B for the equivalent circuit thereof. The conditions of the low-voltage operation process of the low-noise single-gate non-volatile memory structure 100 are:

### In Writing the Memory:

a. V_{sub} is grounded (=0), and
b. V_{d}>Vₛ>0, and V_{c}>Vₛ>0; and

### In Erasing the Memory:

a. V_{sub} is grounded (=0), and
b. V_{d}>V_{c}>Vₛ≧0.

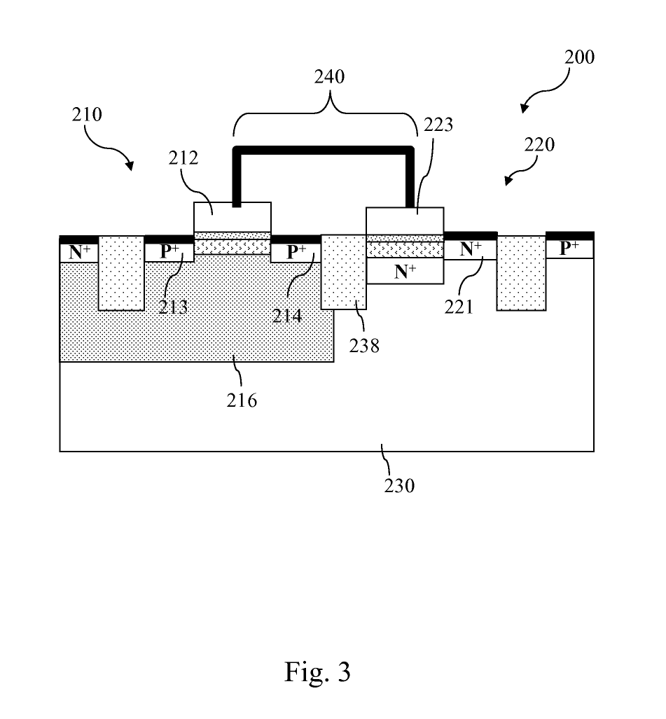

Refer to FIG. 3 a sectional view schematically showing the structure of the low-noise single-gate non-volatile memory according to a second embodiment of the present invention. The low-noise single-gate non-volatile memory structure 200 comprises: a PMOS transistor 210 and an N-type capacitor structure 220 with both of them embedded in a P-type semiconductor substrate 230. The first ion-doped regions of the PMOS transistor 210 are P-type ion-doped regions, and the second ion-doped region 221 and the second ion-doped buried layer 124 of the N-type capacitor structure 220 are N-type ion-doped regions. The low-noise single-gate non-volatile memory structure 200 further comprises an N-type well 216 disposed below the first ion-doped regions. The first electrically-conductive gate 212 of the PMOS transistor 210 and the second electrically-conductive gate 223 on the top of the N-type capacitor structure 220 are also separated with an isolation material 238 and electrically interconnected to form a single floating gate 240.

When the low-noise single-gate non-volatile memory structure 200 is undertaking a low-voltage operation, an N-type well voltage V_{nwell}, a source voltage Vₛ, a drain voltage V_{d}, a control gate voltage V_{c}, and a substrate voltage V_{sub} are respectively applied to the N-type well 216, the source 213, the drain 214, the second ion-doped region 221, and the substrate 230, and the relationship between those voltages is:

### In Writing the Memory:

a. V_{sub} is grounded (=0), and
b. V_{nwell}≧Vₛ>V_{d}>0, and V_{c}>V_{d}>0.

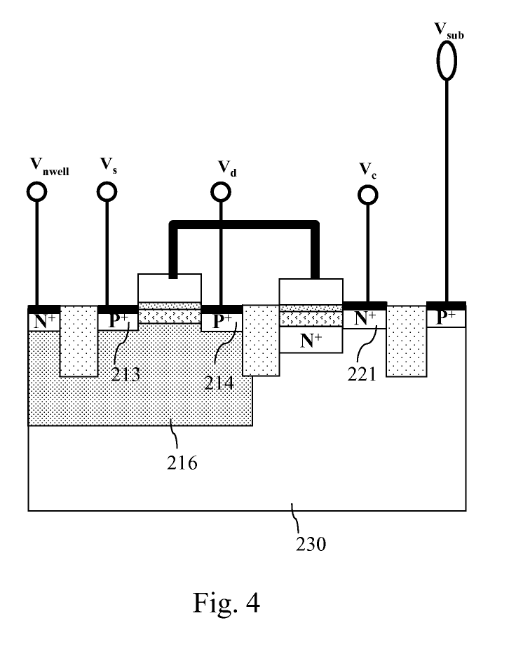

Refer to FIG. 4 a diagram schematically showing the erasing architecture of the low-noise single-gate non-volatile memory structure shown in FIG. 3. The N-type well voltage V_{nwell} must be greater than the substrate voltage V_{sub} lest a junction forward bias occur between the N-type well of the PMOS transistor and the P-type semiconductor substrate. The control gate voltage V_{c} must be great enough lest the PMOS transistor turn on. The drain voltage V_{d} must be increased to be equal to the N-type well voltage V_{nwell}, and the drain voltage V_{d} is equal to the substrate voltage V_{sub} so that the charges of the single floating gate can be erased. The relationship between those voltages is:

### In Erasing the Memory:

a. V_{sub} is grounded (=0), and V_{c}>0, and
b. V_{nwell}≧Vₛ>V_{d}≧0.

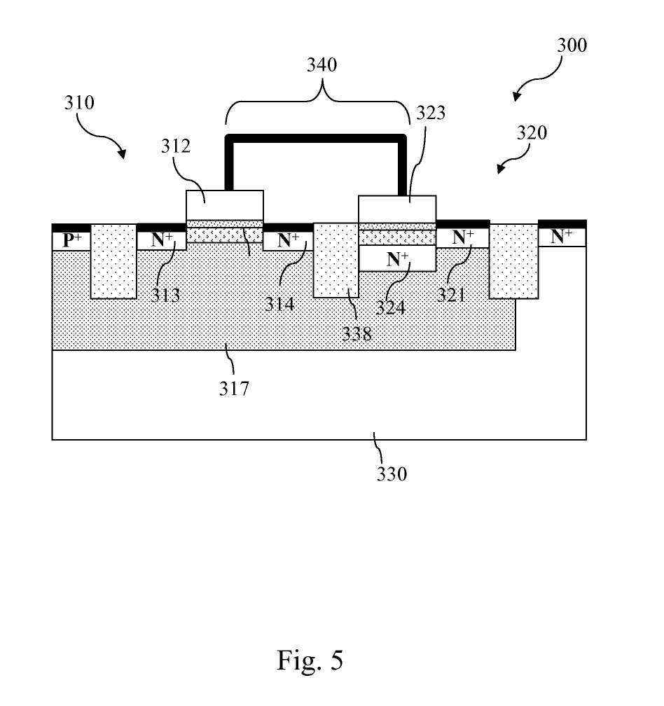

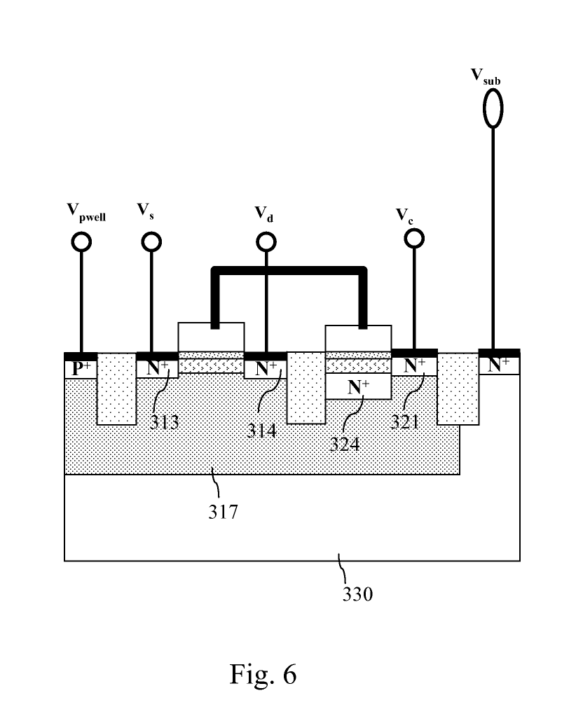

Refer to FIG. 5 a sectional view schematically showing the structure of the low-noise single-gate non-volatile memory according to a third embodiment of the present invention. The low-noise single-gate non-volatile memory structure 300 comprises: an NMOS transistor 310, an N-type capacitor structure 320, and a P-type well 317 with all of them embedded in an N-type semiconductor substrate 330. The NMOS transistor 310 and the N-type capacitor structure 320 are disposed on the surface of the P-type well 317. The first electrically-conductive gate 312 of the NMOS transistor 310 and the second electrically-conductive gate 323 on the top of the N-type capacitor structure 320 are also separated with an isolation material 338 and electrically interconnected to form a single floating gate 340.

When the writing and erasing processes of the low-noise single-gate non-volatile memory structure 300 are undertaken, a P-type well voltage V_{pwell}, a source voltage Vₛ, a drain voltage V_{d}, a control gate voltage V_{c}, and a substrate voltage V_{sub} are respectively applied to the P-type well 317, the source 313, the drain 314, the second ion-doped region 321, and the substrate 330, and the conditions of the low-voltage operation process of the low-noise single-gate non-volatile memory structure 300 are:

### In Writing the Memory:

a. V_{sub} is connected to a power supply, and V_{pwell}=0, and
b. V_{d}>Vₛ>0, and V_{c}>Vₛ>0; and

### In Erasing the Memory:

a. V_{sub} is connected to a power supply, and V_{pwell}=0, and
b. V_{d}>V_{c}>Vₛ≧0.

The memory may also be programmed via the back bias of the substrate, and the operation conditions of the low-noise single-gate non-volatile memory structure 300 are:

### In Writing the Memory:

a. V_{sub} is connected to a power supply, and V_{pwell}>0, and
b. V_{d}>Vₛ>V_{pwell}>0, and V_{c}>Vₛ>V_{pwell}>0; and

### In Erasing the Memory:

a. V_{sub} is connected to a power supply, and V_{pwell} is grounded (=0), and
b. V_{d}>V_{c}>V≧0.

The low-noise single-gate non-volatile memory structure 100 shown in FIG. 1 is formed on a P-type silicon wafer. The isolation structure 138 is fabricated with a standard isolation module process. After the formation of the isolation structure 138, the channel of the NMOS transistor 110 is fabricated with ion-implant processes, and in the N-type capacitor structure 120, the N-type ion-doped buried layer 124 is firstly fabricated on the P-type silicon wafer with ion-implant processes, and then, the channel 115 of the NMOS transistor 110 is fabricated with the same method. After the dielectric layers of the first electrically-conductive gate 112 and the second electrically-conductive gate 123 have been grown, a polysilicon layer is formed via a deposition process. The polysilicon layer is patterned with a photolithographic process and an etching process to form the single floating gate 140. Next, ion-implant processes are undertaken to form the source 113, the drain 114 of the NMOS transistor 110 and the control gate. Lastly, a metallization process is undertaken, and then, the fabrication of the low-noise single-gate non-volatile memory structure 100 is completed.

The fabrication process of the low-noise single-gate non-volatile memory structure 200 shown in FIG. 3 is essentially similar to that described above; however, different patterning processes are undertaken to pattern the N-type well 216 and the source-gate ion-implant region. The low-noise single-gate non-volatile memory structure 300 shown in FIG. 5 is formed on an N-type silicon wafer, and different patterning processes are undertaken to pattern the P-type well 317 and the source-gate ion-implant region. In the present invention, the abovementioned processes usually refer to general CMOS processes. In the present invention, when the memory is programmed, a voltage is applied to the source of the low-noise single-gate non-volatile memory structure. The source voltage will induce a reverse bias in the junction between the source and the substrate. The potential drop between the source and the drain enables the carriers of the channel to move from the source to the drain. The reverse bias between the source and the substrate even expands to the depleted junction region, which can raise the carrier density in the neighborhood of the channel surface. The high carrier density in the neighborhood of the channel surface can promote the current-enhancing effect of the gate and reduce the total current required in programming the memory. Further, the programming speed and reliability can be promoted, and the programming interference can be reduced, thereby. In comparison with the conventional technologies that do not adopt the source-voltage technology, the current-enhancing efficiency of the gate in the present invention is several hundred times higher than that in the conventional technologies.

Further, in the present invention, the F-N tunneling current is increased via raising drain voltage and applying a minor voltage to the gate, and the memory is erased with the increased tunneling current; thereby, a high-speed erasion is achieved.

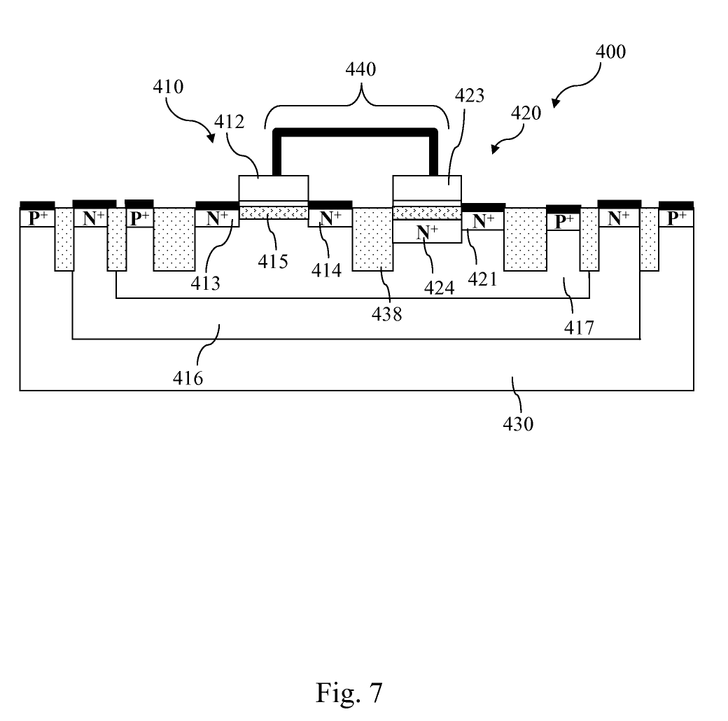

Refer to FIG. 7 a sectional view schematically showing the structure of the low-noise single-gate non-volatile memory according to a fourth embodiment of the present invention. In the low-noise single-gate non-volatile memory structure 400, an isolation well 438 is used to separate an NMOS transistor 410 and an N-type capacitor 420. The NMOS transistor 410 further comprises a second ion-doped buried layer 424, which is disposed below the dielectric layer structure and neighbors a second ion-doped region 421.

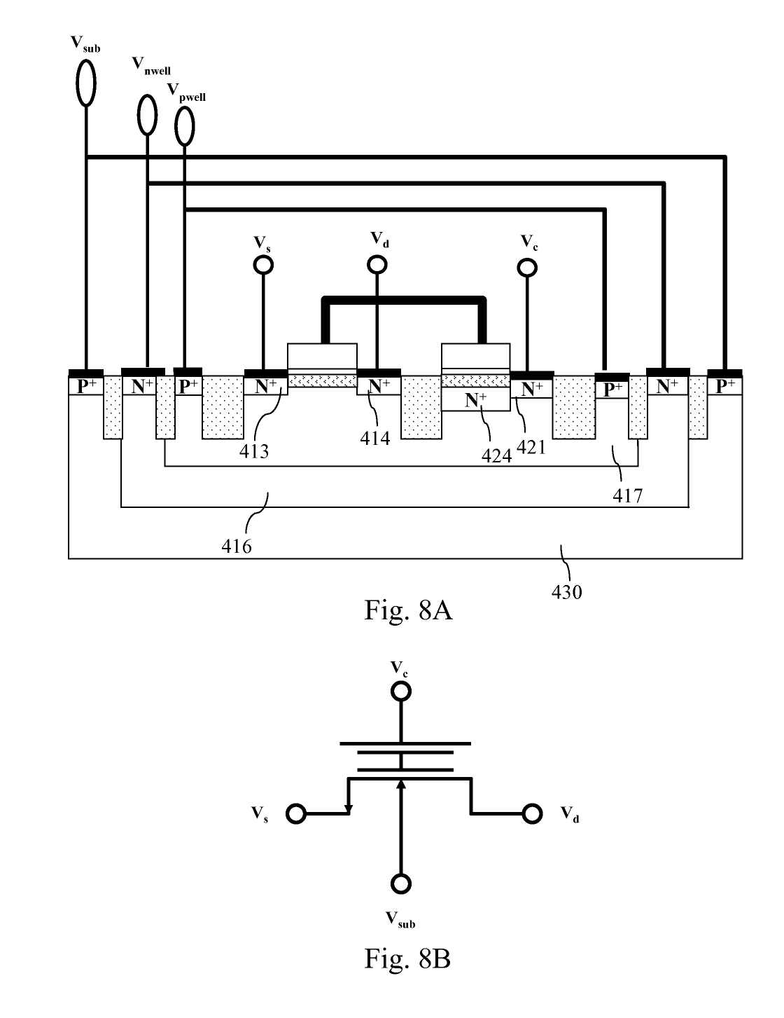

In the present invention, positive voltage and negative voltage are jointly used to further decrease absolute operational voltage and current. Refer to FIG. 7 and FIG. 8A. The low-noise single-gate non-volatile memory structure 400 is a six-terminal structure. Those six terminals include: the connecting structures of the substrate, the N-type well, the P-type well, the source, the drain, and the control gate; a substrate voltage V_{sub}, an N-type well voltage V_{nwell}, a P-type well voltage V_{pwell}, a source voltage Vₛ, a drain voltage V_{d}, and a control gate voltage V_{c} are respectively applied to the substrate 430, the N-type well 416, the P-type well 417, the source 413, the drain 414, and the second ion-doped region 421. Refer to FIG. 8B for the equivalent circuit thereof. The conditions of the low-voltage operation process of the low-noise single-gate non-volatile memory structure 400 are:

### In Writing the Memory:

a. V_{sub} is grounded (=0), and V_{pwell} is a negative voltage, and V_{nwell} is a positive voltage, and
b. Vₛ>V_{pwell}, and Vₛ<V_{d}, and V_{c}>Vₛ; and

### In Erasing the Memory:

a. V_{sub} is grounded (=0), and V_{pwell} is a negative voltage, and V_{nwell} is a positive voltage, and
b. Vₛ≧V_{pwell}, and Vₛ<V_{d}, and V_{c}>Vₛ.

The low-noise single-gate non-volatile memory structure 400 shown in FIG. 7 is formed on a P-type silicon wafer. The isolation structure 438 is fabricated with a standard isolation module process. After the formation of the isolation structure 438, the N-type well 416, the P-type well 417, the N-type ion-doped buried layer 424 and the channel 415 of the NMOS transistor 410 are fabricated with ion-implant processes. After the dielectric layers of the first electrically-conductive gate 412 and the second electrically-conductive gate 423 have been grown, a polysilicon layer is formed via a deposition process. The polysilicon layer is patterned with a photolithographic process and an etching process to form the single floating gate 440. Next, ion-implant processes are undertaken to form the source 413, the drain 414 of the NMOS transistor 410 and the control gate. Lastly, a metallization process is undertaken, and then, the fabrication of the low-noise single-gate non-volatile memory structure 400 is completed.

Thus, the operation method of the low-noise single-gate non-volatile memory of the present invention can greatly reduce the current consumed in programming the low-noise single-gate non-volatile memory. Further, the method of the present invention can also accelerate the speed of erasing the low-noise single-gate non-volatile memory via raising the gate voltage to be relatively higher than the drain voltage and the transistor substrate voltage.

Besides, the present invention also provides a fifth embodiment, wherein a negative voltage is applied to the P-type well so that the absolute voltage of the drain or the gate can be decreased (less than 5V) in writing or erasing the memory. Thereby, the present invention can achieve the objectives of low operation voltage and low current consumption in a single-gate non-volatile memory.

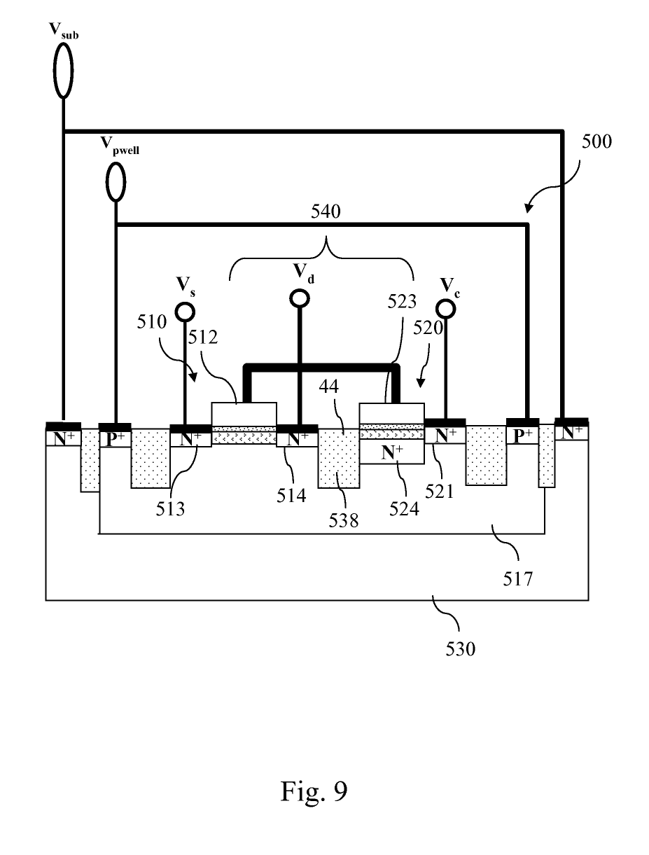

Refer to FIG. 9 a sectional view schematically showing the structure of the low-noise single-gate non-volatile memory according to the fifth embodiment of the present invention. The low-noise single-gate non-volatile memory structure 500 comprises: an NMOS transistor 510 and an N-type capacitor structure 520 with both of them disposed in a P-type well 517. A second ion-doped buried layer 524 is formed below the dielectric layer of the N-type capacitor structure 520, and the second ion-doped buried layer 524 neighbors the P-type well 517. The P-type well 517 are disposed on an N-type semiconductor 530. The first electrically-conductive gate 512 of the NMOS transistor 510 and the second electrically-conductive gate 523 on the top of the N-type capacitor structure 520 are separated with an isolation material 538 and electrically interconnected to form a single floating gate 540.

When the writing and erasing processes of the low-noise single-gate non-volatile memory structure 500 are undertaken, a substrate voltage V_{sub}, a P-type well voltage V_{pwell}, a source voltage Vₛ, a drain voltage V_{d}, and a control gate voltage V_{c} are respectively applied to the substrate 530, the P-type well 517, the source 513, the drain 514, and the second ion-doped region 521, and the conditions of the low-voltage operation process of the low-noise single-gate non-volatile memory structure 500 are:

### In Writing the Memory:

a. V_{sub} is connected to a power supply, and V_{pwell} is a negative voltage, and
b. V_{sub}>V_{pwell}, and Vₛ<V_{d}, and V_{c}>Vₛ; and

### In Erasing the Memory:

a. V_{sub} is connected to a power supply, and V_{pwell} is a negative voltage, and
b. Vₛ≧V_{pwell}, and Vₛ<V_{d}, and V_{c}>Vₛ.

Those embodiments described above are to clarify the present invention to enable the persons skilled in the art to understand, make and use the present invention; however, it is not intended to limit the scope of the present invention, and any equivalent modification and variation according to the spirit of the present is to be also included within the scope of the claims stated below.

What is claimed is:

1. A single-gate non-volatile memory, comprising:
a semiconductor substrate;
a transistor, formed in said semiconductor substrate, and further comprising:
a first dielectric layer, disposed on a surface of said semiconductor substrate;
a first electrically-conductive gate, disposed on said first dielectric layer; and
multiple first ion-doped regions, separately disposed at both sides of said first electrically-conductive gate, and respectively functioning as a source and a drain; and
a capacitor structure, formed in said semiconductor substrate, and further comprising:
a second dielectric layer, disposed on a surface of said semiconductor substrate;
a second electrically-conductive gate, disposed on said second dielectric layer;
a second ion-doped buried layer, disposed between said second dielectric layer and said semiconductor substrate; and
a second ion-doped region, disposed at one side of said second dielectric layer, with said first electrically-conductive gate and said second electrically-conductive gate being separated but electrically interconnected to form a single floating gate.

2. The single-gate non-volatile memory according to claim 1, wherein said semiconductor substrate is a P-type one or an N-type one.

3. The single-gate non-volatile memory according to claim 1, wherein said first ion-doped regions and said second ion-doped region are doped with a first type ion, and said semiconductor substrate is doped with a second type ion, and said first type ion is different from said second type ion.

4. The single-gate non-volatile memory according to claim 3, wherein said semiconductor substrate is a P-type semiconductor substrate, and said first ion-doped regions and said second ion-doped region are N-type ion-doped regions.

5. The single-gate non-volatile memory according to claim 3, wherein said semiconductor substrate is an N-type semiconductor substrate, and said first ion-doped regions and said second ion-doped region are P-type ion-doped regions.

6. The single-gate non-volatile memory according to claim 1, further comprising a third ion-doped region, which is embedded inside said semiconductor substrate and is disposed below said first ion-doped regions and is doped with the same type ion as said second ion-doped region.

7. The single-gate non-volatile memory according to claim 6, wherein said third ion-doped region extends to the region below said second ion-doped buried layer.

8. The single-gate non-volatile memory according to claim 7, further comprising an isolation well, which is embedded inside said semiconductor substrate, wherein said isolation well and said second ion-doped region are doped with a first type ion, and said third ion-doped region and said semiconductor substrate are doped with a second type ion, and said first type ion is different from said second type ion.

9. The single-gate non-volatile memory according to claim 6, wherein said semiconductor substrate is an N-type semiconductor substrate, and said second ion-doped region and said third ion-doped region are P-type ion-doped regions.

10. The single-gate non-volatile memory according to claim 6, wherein said semiconductor substrate is a P-type semiconductor substrate, and said second ion-doped region and said third ion-doped region are N-type ion-doped regions.

11. The single-gate non-volatile memory according to claim 1, wherein said second ion-doped buried layer is an N+ buried layer.

12. The single-gate non-volatile memory according to claim 1, wherein a first channel structure is formed between said transistor and said semiconductor substrate.

13. The single-gate non-volatile memory according to claim 1, wherein a second channel structure is formed between said capacitor structure and said semiconductor substrate, and said second ion-doped buried layer is disposed below said second channel structure.

14. An operation method of a single-gate non-volatile memory, wherein said single-gate non-volatile memory comprises:
a P-type semiconductor substrate;
a transistor, disposed in said P-type semiconductor substrate, and further comprising: a first electrically-conductive gate and multiple first ion-doped regions that are separately disposed at both sides of said first electrically-conductive gate and respectively function as a source and a drain; and
a capacitor structure, disposed in said P-type semiconductor substrate, and further comprising: a second electrically-conductive gate, a second ion-doped region and a second ion-doped buried layer with said first electrically-conductive gate and said second electrically-conductive gate electrically interconnected to form a single floating gate; and
wherein said operation method is characterized in:
a substrate voltage V_{sub}, a source voltage Vₛ, a drain voltage V_{d}, a control gate voltage V_{c} are respectively applied to said P-type semiconductor substrate, said source, said drain and said second ion-doped region, and said voltages meet the following conditions: in writing said memory:
V_{sub} is grounded, and
V_{d}>Vₛ>0, and
V_{c}>Vₛ>0; and
in erasing said memory:
V_{sub} is grounded, and
V_{d}>V_{c}>Vₛ≧0.

15. An operation method of a single-gate non-volatile memory,
wherein said single-gate non-volatile memory comprises:
a P-type semiconductor substrate;
a transistor, disposed in said P-type semiconductor substrate, and further comprising: a first electrically-conductive gate and multiple first ion-doped regions that are separately disposed at both sides of said first electrically-conductive gate and respectively function as a source and a drain;
an N-type well, disposed below said first ion-doped regions; and
a capacitor structure, disposed in said P-type semiconductor substrate, and further comprising: a second electrically-conductive gate, a second ion-doped region and a second ion-doped buried layer with said first electrically-conductive gate and said second electrically-conductive gate electrically interconnected to form a single floating gate; and
wherein said operation method is characterized in:
a substrate voltage V_{sub}, an N-type well voltage V_{nwell}, a source voltage Vₛ, a drain voltage V_{d}, and a control gate voltage V_{c} are respectively applied to said P-type semiconductor substrate, said N-type well, said source, said drain and said second ion-doped region, and said voltages meet the following conditions:
in writing said memory:
V_{sub} is grounded, and
V_{nwell}≧Vₛ>V_{d}>0, and
V_{c}>V_{d}>0; and
in erasing said memory:
V_{sub} is grounded, and
V_{c}>0, and
V_{nwell}≧Vₛ>V_{d}≧0.

16. An operation method of a single-gate non-volatile memory,
wherein said single-gate non-volatile memory comprises:
an N-type semiconductor substrate;
a P-type well, disposed in said N-type semiconductor substrate;
a transistor, disposed on the surface of said P-type well, and further comprising: a first electrically-conductive gate and multiple first ion-doped regions that are separately disposed at both sides of said first electrically-conductive gate and respectively function as a source and a drain; and
a capacitor structure, disposed on a surface of said P-type well, and further comprising: a second electrically-conductive gate, a second ion-doped region and a second ion-doped buried layer with said first electrically-conductive gate and said second electrically-conductive gate electrically interconnected to form a single floating gate; and
wherein said operation method is characterized in:
a substrate voltage V_{sub}, a P-type well voltage V_{pwell}, a source voltage Vₛ, a drain voltage V_{d}, and a control gate voltage V_{c} are respectively applied to said N-type semiconductor substrate, said P-type well, said source, said drain and said second ion-doped region, and said voltages meet the following conditions:
in writing said memory:
V_{sub} is connected to a power supply, and
V_{d}>Vₛ>V_{pwell}, and
V_{c}>Vₛ>V_{pwell}; and
in erasing said memory:
V_{sub} is connected to a power supply, and
V_{c}>Vₛ>V_{pwell}, and
V_{d}>Vₛ>V_{pwell}.

17. The operation method of a single-gate non-volatile memory according to claim 16, wherein in writing said memory, V_{pwell}>0.

18. The operation method of a single-gate non-volatile memory according to claim 16, wherein in erasing said memory, V_{pwell}>0.

19. The operation method of a single-gate non-volatile memory according to claim 16, wherein in erasing said memory, V_{d}>V_{c}>Vₛ≧0.

20. An operation method of a single-gate non-volatile memory,
wherein said single-gate non-volatile memory comprises:
a P-type semiconductor substrate;
an N-type well, disposed in said P-type semiconductor substrate;
a P-type well, disposed in said N-type well;
a transistor, disposed on a surface of said P-type well, and further comprising: a first electrically-conductive gate and multiple first ion-doped regions that are separately disposed at both sides of said first electrically-conductive gate and respectively function as the source and the drain; and
a capacitor structure, disposed on the surface of said P-type well, and further comprising: a second electrically-conductive gate and a second ion-doped region and a second ion-doped buried layer with said first electrically-conductive gate, said second electrically-conductive gate electrically interconnected to form a single floating gate; and
wherein said operation method is characterized in:
a substrate voltage V_{sub}, a source voltage Vₛ, a drain voltage V_{d}, a P-type well voltage V_{pwell}, an N-type well voltage V_{nwell}, and a control gate voltage V_{c} are respectively applied to said P-type semiconductor substrate, said source, said drain, said P-type well, said N-type well and said second ion-doped region, and said substrate voltage V_{sub}, said source voltage Vₛ, said drain voltage V_{d}, said P-type well voltage V_{pwell}, said N-type well voltage V_{nwell}, and said control gate voltage V_{c} meet the following conditions:
in writing said memory:
V_{c}>Vₛ>V_{pwell}, and
V_{d}>Vₛ>V_{pwell}, and
V_{sub} is grounded, and
V_{nwell}≧0; and
in erasing said memory:
V_{c}>Vₛ>V_{pwell}, and
V_{d}>Vₛ>V_{pwell}, and
V_{sub} is grounded, and
V_{nwell}>0.
